(19) United States
(12) Patent Application Publication
(10) Pub. No.: US 2022/0033958 A1
(43) Pub. Date: Feb. 3, 2022

(54) EVAPORATION SOURCE, VAPOR DEPOSITION APPARATUS, AND METHOD FOR COATING A SUBSTRATE IN A VACUUM CHAMBER

(71) Applicant: Applied Materials, Inc., Santa Clara, CA (US)

(72) Inventors: Thomas DEPPISCH, Aschaffenburg (DE); Stefan BANGERT, Steinau (DE); Annabelle HOFMANN, Stockstadt (DE); Andreas LOPP, Freigericht-Somborn (DE); Thomas GOIHL, Eschau (DE)

(21) Appl. No.: 16/944,511

(22) Filed: Jul. 31, 2020

(51) Int. Cl. C23C 14/24; C23C 14/04; C23C 14/50

(52) U.S. Cl. CPC C23C 14/243; C23C 14/505; C23C 14/042

(57) ABSTRACT

An evaporation source for depositing an evaporated material on a substrate is described. The evaporation source includes an evaporation crucible for evaporating a material; a vapor distributor with a plurality of nozzles for directing the evaporated material toward the substrate; a vapor conduit extending in a conduit length direction (A) from the evaporation crucible to the vapor distributor and providing a fluid connection between the evaporation crucible and the vapor distributor, wherein at least one nozzle of the plurality of nozzles has a nozzle axis extending in, or essentially parallel to, the conduit length direction (A); and a baffle arrangement in the vapor conduit. Further described are a vapor deposition apparatus including such an evaporation source and methods of coating a substrate in a vacuum chamber.

### TECHNICAL FIELD

Embodiments of the present disclosure relate to substrate coating by thermal evaporation in a vacuum chamber. Embodiments of the present disclosure particularly relate to the deposition of one or more coating strips on a flexible web substrate via evaporation, e.g. on a flexible metal foil, in a roll-to-roll deposition system. In particular, embodiments relate to the deposition of lithium on a flexible foil, e.g. for the manufacture of Li-batteries. Specifically, embodiments relate to an evaporation source for depositing an evaporated material on a substrate, a vapor deposition apparatus with an evaporation source, and a method for coating a substrate in a vacuum chamber.

### BACKGROUND

Various techniques for depositing a coating on a substrate are known, for example, chemical vapor deposition (CVD) and physical vapor deposition (PVD). For deposition at high deposition rates, thermal evaporation may be used: a material is heated up in an evaporation source to produce a vapor that is directed toward a substrate for forming a coating layer on the substrate.

In evaporation sources, the material to be deposited is typically heated in an evaporation crucible to produce vapor at an elevated vapor pressure. The vapor can be guided from the evaporation crucible to a heated vapor distributor that includes a plurality of nozzles. The vapor can be directed by the plurality of nozzles onto the substrate, for example, in a vacuum chamber.

The substrate may be a flexible substrate, such as a foil or web substrate. The web substrate may be guided on and supported by a rotatable coating drum with a curved drum surface. Specifically, the vapor may be deposited on the web substrate while the web substrate moves on the curved drum surface of the rotatable drum past the evaporation source. Accordingly, the plurality of nozzles of the evaporation source may be directed toward the curved drum surface that acts as the substrate support. Vapor deposition systems for coating a web substrate being guided on a rotatable coating drum are also referred to herein as roll-to-roll (R2R) deposition systems.

Typically, the available space at the periphery of a rotatable coating drum is limited, such that a compact evaporation source is beneficial in a R2R deposition system. If the substrate moves during the deposition past the evaporation source at a given speed, e.g., on a rotating drum, the deposition rate needs to be accurately adjusted for depositing a uniform coating with a predetermined thickness on the substrate. For example, if the deposition rate is inadvertently increased, e.g. due to a change of temperature or pressure in the evaporation source, the coating thickness may increase as well. Further, if the deposition rate per area on the substrate increases locally above an allowable threshold value, there is a risk of damaging the flexible substrate due to an excessive heat load. However, accurately controlling the deposition rate is challenging, particularly if the evaporation source is a small and compact source arranged at the periphery of a rotatable coating drum.

Accordingly, it would be beneficial to provide evaporation sources, particularly for a R2R deposition system, as well as coating methods that ensure a predetermined deposition rate and provide a reduced risk of substrate damage. Such an evaporation source can be beneficially used in a vapor deposition system that includes a rotatable drum. Further, it would be beneficial to provide vapor deposition systems with a rotatable drum suitable for coating a web substrate at a predetermined deposition rate with a reduced risk of substrate damages and with an improved coating quality.

### SUMMARY

In light of the above, an evaporation source, a vapor deposition apparatus, and a method for coating a substrate in a vacuum chamber according to the independent claims are provided. Further aspects, advantages and features of the present disclosure are apparent from the description and the accompanying drawings.

According to one aspect, an evaporation source for depositing an evaporated material on a substrate is provided. The evaporation source includes: an evaporation crucible for evaporating a material; a vapor distributor with a plurality of nozzles for directing the evaporated material toward the substrate; a vapor conduit extending in a conduit length direction from the evaporation crucible to the vapor distributor and providing a fluid connection between the evaporation crucible and the vapor distributor, wherein at least one nozzle of the plurality of nozzles has a nozzle axis extending in, or essentially parallel to, the conduit length direction; and a baffle arrangement in the vapor conduit.

In some embodiments, the baffle arrangement may be configured to at least one of: (1) reduce heat radiation from the vapor distributor into the evaporation crucible through the vapor conduit; and (2) reduce or prevent material splashes from the evaporation crucible into the vapor distributor through the vapor conduit. Specifically, thermal crosstalk between the evaporation crucible and the vapor distributor is reduced by the baffle arrangement, such that the evaporation rate in the evaporation crucible can be more accurately controlled by adjusting the temperature of a crucible heater.

According to one aspect, a vapor deposition apparatus is provided. The vapor deposition apparatus includes an evaporation source according to any of the embodiments described herein and a rotatable drum with a curved drum surface for supporting the substrate. The plurality of nozzles of the evaporation source is directed toward the curved drum surface, and the vapor deposition apparatus is configured to move the substrate on the curved drum surface past the evaporation source.

In some embodiments, the plurality of nozzles is arranged in a plurality of nozzle rows arranged next to each other, each nozzle row including five or more nozzles. The nozzle axes of some or all the nozzles of the plurality of nozzles may extend in, or essentially parallel to, the conduit length direction.

According to one aspect, a method for coating a substrate in a vacuum chamber is provided. The method includes: evaporating a material in an evaporation crucible; guiding the evaporated material through a vapor conduit into a vapor distributor with a plurality of nozzles, the vapor conduit extending in a conduit length direction; directing the evaporated material with the plurality of nozzles toward the substrate, the plurality of nozzles having nozzle axes extending in, or essentially parallel to, the conduit length direction; and reducing heat radiation from the vapor distributor into the evaporation crucible and/or splashes from the evaporation crucible into the vapor distributor with a baffle arrangement arranged in the vapor conduit.

According to another aspect, a vapor deposition apparatus is provided. The vapor deposition apparatus includes a rotatable drum with a curved drum surface for supporting a substrate and at least one evaporation source for depositing an evaporated material on the substrate. The at least one evaporation source includes: an evaporation crucible for evaporating a material; a vapor distributor with a plurality of nozzles directed toward the curved drum surface, the plurality of nozzles arranged in a plurality of nozzle rows extending in a row direction and arranged next to each other; and a vapor conduit extending in a conduit length direction from the evaporation crucible to the vapor distributor and providing a fluid connection between the evaporation crucible and the vapor distributor. The nozzles have nozzle axes extending in, or essentially parallel to, the conduit length direction. The at least one evaporation source may optionally further include a baffle arrangement as described herein in the vapor conduit.

According to one aspect, a method of manufacturing a coated substrate in the vapor deposition apparatus according to any of the embodiments described herein is provided. The method includes supporting a substrate on a curved drum surface of a rotatable drum of the vapor deposition apparatus; and directing vapor from the evaporation source of the vapor deposition apparatus toward the substrate for depositing one or more coating strips on the substrate. The coated substrate may be an anode, or may form part of an anode, for manufacturing a thin film battery, e.g., a lithium battery.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the present disclosure are also directed at methods for manufacturing the described apparatuses and products, and methods of operating the described apparatus. Described embodiments include method aspects for carrying out every function of the described apparatuses.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 shows a schematic sectional view of an evaporation source according to embodiments of the present disclosure;

FIG. 2 shows a schematic perspective view of the baffle arrangement of the evaporation source of FIG. 1;

FIG. 3 shows a schematic front view of an evaporation source according to embodiments of the present disclosure;

FIG. 4 shows a schematic sectional view of a vapor deposition apparatus according to embodiments of the present disclosure;

FIG. 5 shows a schematic view of the vapor deposition apparatus of FIG. 4 viewed along a rotation axis of a rotatable drum;

FIG. 6 shows a flowchart illustrating a method of coating a substrate according to embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

Within the following description of the drawings, the same reference numbers refer to the same or similar components. Generally, only the differences with respect to the individual embodiments are described. Unless specified otherwise, the description of a part or aspect in one embodiment applies to a corresponding part or aspect in another embodiment as well.

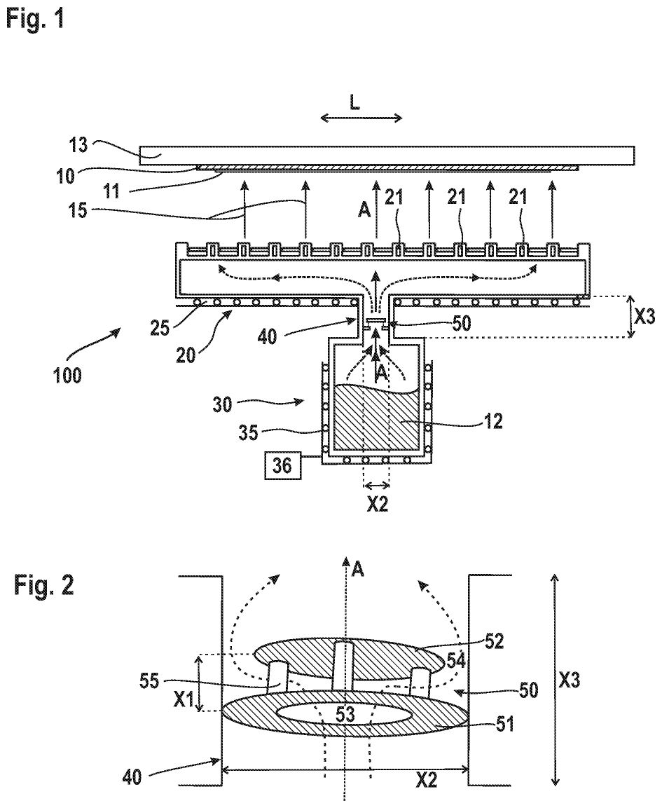

FIG. 1 is a schematic sectional view of an evaporation source 100 for depositing an evaporated material on a substrate 10 according to embodiments described herein. The evaporation source 100 includes an evaporation crucible 30 for heating a solid or liquid source material 12 to a temperature above the evaporation temperature or sublimation temperature of the source material 12, such that the source material 12 evaporates. The evaporation crucible 30 may include an inner volume acting as a material reservoir for accommodating the source material 12 in a solid and/or liquid state, and a first heater 35 for heating the inner volume of the evaporation crucible, such that the source material 12 evaporates. For example, the source material 12 may be a metal, particularly lithium, and the first heater 35 may be configured for heating the inner volume of the crucible to a temperature of 600° C. or more, particularly 700° C. or more, or even 800° C. or more.

The evaporation source 100 further includes a vapor distributor 20 with a plurality of nozzles 21 for directing the material evaporated in the evaporation crucible toward a substrate 10, such that a coating 11 is deposited on the substrate 10. The vapor distributor 20 may include an inner volume that is in fluid communication with the inner volume of the evaporation crucible 30, such that the evaporated material can stream from the inner volume of the evaporation crucible 30 into the inner volume of the vapor distributor 20 through a vapor conduit 40, e.g. along a linear connection tube or passage. The plurality of nozzles 21 may be configured to direct the evaporated material from the inner volume of the vapor distributor 20 toward the substrate 10. For example, the vapor distributor 20 may include ten, thirty, or more nozzles for directing the evaporated material toward the substrate 10 that is supported on a substrate support 13.

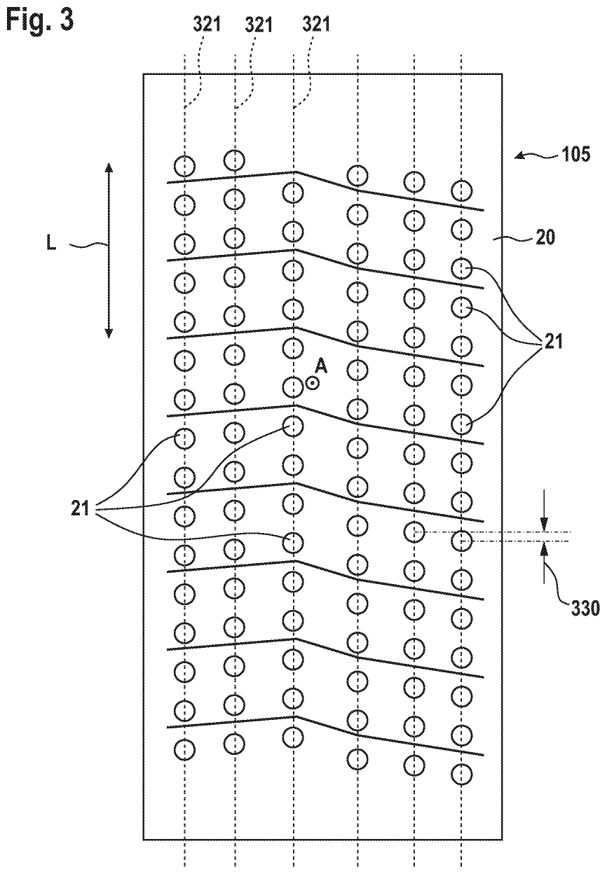

In some embodiments, the vapor distributor 20 may be a vapor distribution showerhead having the plurality of nozzles arranged in a 1-dimensional or 2-dimensional pattern for directing the evaporated material toward the substrate. For example, the vapor distributor 20 may be a linear showerhead having the plurality of nozzles arranged in one row, or the vapor distributor may be an “area showerhead” having the plurality of nozzles in a 2-dimensional array, e.g. in a plurality of nozzle rows 321 arranged next to each other (see FIG. 3).

The evaporation crucible 30 is in fluid connection with the vapor distributor 20 via the vapor conduit 40 that extends from the evaporation crucible 30 to the vapor distributor 20 in a conduit length direction A. The vapor conduit 40 may essentially linearly extend from the evaporation crucible 30 to the vapor distributor in the conduit length direction A. Specifically, the inner volume of the evaporation crucible and the inner volume of the vapor distributor may be connected by the linearly extending vapor conduit. A “linearly extending vapor conduit” may be understood as a passage or tube that does not include strong curves or bends along the length direction thereof. In particular, assuming that there were no obstacles inside the vapor conduit, the evaporated material could stream from the evaporation crucible into the vapor distributor along a linear vapor propagation path. Connecting the evaporation crucible and the vapor distributor via the vapor conduit 40 that extends essentially linearly is advantageous for several reasons: (i) A more compact evaporation source can be provided and space can be saved if the connection between the evaporation crucible and the vapor distributor does not include strong curves or bends. (ii) The vapor distributor can be mounted essentially directly against the evaporation crucible, e.g. by integrally forming the vapor conduit with a vapor exit of the evaporation crucible and/or with a vapor entrance of the vapor distributor, or by fixedly mounting the linear vapor conduit between the vapor exit of the evaporation crucible and the vapor entrance of the vapor distributor. (iii) Considering that, during evaporation, the whole inner volume of the evaporation source should be maintained above the evaporation temperature in order to avoid material condensation, heating efforts can be reduced and more compact heaters can be provided if the vapor distributor is mounted close to and in linear connection to the evaporation crucible.

In some embodiments, a length X3 of the vapor conduit 40 in the conduit length direction A may be 30 cm or less, particularly 20 cm or less, more particularly 10 cm or less. In other words, the distance between the evaporation crucible 30 and the vapor distributor 20 may be 30 cm or less, particularly 20 cm or less, or even 10 cm or less. Accordingly, the vapor distributor may be arranged directly downstream of the evaporation crucible. Alternatively or additionally, a width dimension X2 of the vapor conduit 40 in a direction perpendicular to the conduit length direction A may be 15 cm or less, particularly 10 cm or less. For example, the vapor conduit may be a tubular connection between the evaporation crucible and the vapor distributor having a length of 30 cm or less and a diameter of 15 cm or less.

According to embodiments described herein, at least one nozzle of the plurality of nozzles 21 has a nozzle axis extending in, or essentially parallel to, the conduit length direction A. “Essentially parallel” may be understood to mean that an angle between the conduit length direction A and the nozzle axis is 20° or less, particularly 10° or less. In particular, the nozzle axes of some nozzles or of all the nozzles of the plurality of nozzles 21 may extend in, or essentially parallel to, the conduit length direction A, as it is schematically depicted in FIG. 1. Accordingly, the plurality of nozzles 21 is configured to direct the vapor 15 toward the substrate in a nozzle main emission direction that essentially corresponds to the length direction of the vapor conduit. This improves the fluid conductance of vapor flow passages in the evaporation source and allows a more uniform vapor flow toward and through the plurality of nozzles. In other words, the connection direction of the evaporation crucible and the vapor distributor may essentially correspond to the vapor main emission direction of the plurality of nozzles. For example, both the conduit length direction A and the nozzle axes may be vertical directions or may enclose angles of 45° or less with the vertical direction.

During evaporation, the vapor distributor 20 is typically provided at a second temperature that is higher than a first temperature inside the evaporation crucible 30 in order to prevent a material condensation on inner wall surfaces of the vapor distributor. This may lead to a heat radiation from the inner volume of the vapor distributor 20 into the inner volume of the evaporation crucible 30. This heat radiation may be significant if the evaporation crucible 30 and the vapor distributor 20 are linearly connected. Specifically, heat may radiate from the heated vapor distributor 20 through the vapor conduit 40 into the inner volume of the evaporation crucible 30 where the source material 12 is accommodated, inadvertently increasing the crucible temperature and increasing also the evaporation rate inside the evaporation crucible. Hence, the heat radiation from the vapor distributor can make it difficult to accurately adjust the evaporation rate in the evaporation crucible by adjusting the temperature in the evaporation crucible, particularly if the evaporation crucible and the vapor distributor are linearly connected.

Further, due to the linear connection of the evaporation crucible and the vapor distributor in a direction that corresponds to the direction of the nozzle axis A, splashes or droplets of the source material 12 that are not yet in a vapor state from the evaporation crucible may splash upwards through the vapor conduit 40 and even through one or more nozzles of the plurality of nozzles and may end up on the substrate. The coating uniformity on the substrate may be negatively affected, and the substrate may even get damaged due to the heat that is transmitted on the substrate by a liquid droplet.

According to embodiments described herein, the above-described problems are solved by arranging a baffle arrangement 50 in the vapor conduit 40. The baffle arrangement 50 may be configured to reduce the heat radiation from the vapor distributor 20 into the evaporation crucible 30 through the vapor conduit 40. Alternatively or additionally, the baffle arrangement 50 may be configured to reduce or prevent material splashes from the evaporation crucible 30 into the vapor distributor 20 and/or through the plurality of nozzles 21 toward the substrate.

The heat radiation through the vapor conduit 40 can be reduced by providing the baffle arrangement 50 in the vapor conduit 40 that blocks and/or reflects heat radiation from the inner volume of the vapor distributor 20. For example, the baffle arrangement 50 may be made of polished metal or may have a polished metal coating or may be made of or coated with a material having a thermal emissivity value less than 0.2, particularly less than 0.1. The baffle arrangement 50 may block some or all linear vapor propagation paths through the vapor conduit 40, such that heat radiation from the vapor distributor toward the evaporation crucible necessarily “hits” the baffle arrangement that may include a low thermal emissivity material, reducing the heat radiation into the crucible.

Accordingly, the heat load into the evaporation crucible 30 from the vapor distributor 20 is reduced, such that the first temperature inside the evaporation crucible 30 can be controlled more independently of the second temperature inside the vapor distributor 20. This allows a more accurate control of the evaporation rate in the evaporation crucible, such that a more uniform deposition on the substrate can be achieved.

Further, splashes through the vapor conduit 40 from the evaporation crucible can be reduced or prevented by providing the baffle arrangement 50 in the vapor conduit 40. The baffle arrangement 50 may block all linear vapor propagation paths through the vapor conduit, such that splashes from the evaporation crucible into the vapor conduit cannot get through the vapor conduit but may hit the inner wall of the vapor conduit or the baffle arrangement 50. The risk of substrate damage by material splashes from the evaporation crucible through the plurality of nozzles is reduced, and a more uniform coating on the substrate can be provided. Further, the risk of substrate damage by material drops can be reduced or eliminated.

In some embodiments, which can be combined with other embodiments described herein, the baffle arrangement 50 blocks all linear vapor propagation paths through the vapor conduit from the evaporation crucible to the vapor distributor. In other words, the vapor propagation paths through the vapor conduit are necessarily curved due to the shape and/or positioning of the baffle arrangement.

For example, the baffle arrangement 50 may include one or more shielding plates that may extend essentially perpendicular to the conduit length direction A in the vapor conduit. The one or more shielding plates may be fixedly mounted in the vapor conduit, e.g. via clamps, screws or bolts. Specifically, the one or more shielding plates may be immovably fixed at respective shielding positions in the vapor conduit. Fixedly mounting one or more shielding plates in the vapor conduit is possible without great effort and leads to an effective thermal separation and thermal decoupling of the evaporation crucible from the vapor distributor, such that the temperatures inside the evaporation crucible and inside the vapor distributor can be controlled more independently.

FIG. 2 is an enlarged view of an exemplary baffle arrangement 50 that is arranged in the vapor conduit 40. The baffle arrangement 50 includes shielding plates that extend essentially perpendicular to the conduit length direction A.

In some embodiments, which can be combined with other embodiments described herein, the baffle arrangement 50 includes a first shielding plate 51 and a second shielding plate 52 that are spaced apart from each other in the conduit length direction A and are arranged such that vapor can stream past the baffle arrangement 50 only along curved vapor propagation paths. Specifically, the first shielding plate 51 may leave a first vapor passage 53 past the first shielding plate 51 and the second shielding plate 52 may leave a second vapor passage 54 past the second shielding plate 52, wherein the second vapor passage 54 does not overlap with the first vapor passage 53 in the conduit length direction A.

In some embodiments, the second shielding plate 52 is arranged downstream of an opening or other recess in the first shielding plate 51, such that droplets that may splash through the opening or recess in the first shielding plate 51 are shielded by the second shielding plate 52. In particular, the shape of the second shielding plate 52 may be adapted to the shape of an opening or recess provided by the first shielding plate 51. For example, the first and second shielding plates may have essentially complementary shapes, and/or the combined shapes of the first and second shielding plates may correspond to the inner sectional shape of the vapor conduit 40.

In some implementations, the second shielding plate 52 is arranged downstream of an opening or recess in the first shielding plate and overlaps with an edge of the opening or recess in the conduit length direction A. Accordingly, vapor streaming past the baffle arrangement 50 always streams along curved vapor propagation paths.

In some embodiments, the baffle arrangement 50 may include three or more shielding plates arranged subsequently along the vapor conduit and shaped and arranged such that vapor propagation paths past the baffle arrangement 50 have two or more curves or bends and/or have a curvature that changes several times. Heat radiation through the vapor conduit can be more effectively blocked or shielded.

In some implementations, the second shielding plate 52 may be arranged at a distance X1 of 5 cm or less, particularly 3 cm or less, or even 2 cm or less from the first shielding plate 51 in the conduit length direction A. Hence, the curvature of vapor propagation paths through the vapor conduit is increased and the risk of droplets splashing through the vapor conduit can be further decreased. In some embodiments, the distance X1 between the first and second shielding plates may essentially correspond to the length X3 of the vapor conduit 40. For example, the length X3 of the vapor conduit may be 5 cm or less, and the distance X1 may essentially correspond to X3. This allows space to be saved and provides a compact evaporation source. The first shielding plate 51 may have an opening, and the second shielding plate 52 may cover the opening and/or may overlap with an edge of the opening, blocking all linear vapor propagation paths through the opening past the second shielding plate 52.

In some embodiments, which can be combined with other embodiments described herein, the baffle arrangement 50 includes a first shielding plate 51 and a second shielding plate 52, wherein the first shielding plate 51 is an annular plate that has a round or circular opening, and the second shielding plate 52 is a round or circular plate that is centrally arranged in the vapor conduit 40 downstream or upstream of the opening and shields the opening. The annular shielding plate may circumferentially abut at an inner wall of the vapor conduit, as it is schematically depicted in FIG. 2, such that droplets cannot splash through a gap between the first shielding plate 51 and an inner wall of the vapor conduit 40 past the baffle arrangement.

The first shielding plate 51 and the second shielding plate 52 may be fixedly and immovably connected to each other via connectors 55, e.g. via spacers extending along the conduit length direction A and holding the shielding plates spaced-apart from each other in the vapor conduit 40. For example, the first and second shielding plates may be mounted by at least one of clamps, screws, bolts and nuts. Specifically, spacers arranged between the shielding plates may be fixed to both the first shielding plate 51 and the second shielding plate 52 via bolts and/or nuts.

Returning now to FIG. 1, the evaporation source 100 may further include a first heater 35 for heating and evaporating the source material 12 in the evaporation crucible 30 and a second heater 25 for heating an inner volume of the vapor distributor. The first heater 35 and the second heater 25 can be individually controlled. For example, the first heater 35 may be configured to heat the evaporation crucible to a first temperature and the second heater 25 may be configured to heat the vapor distributor to a second temperature different from the first temperature, particularly above the first temperature. During the vapor deposition, the inner volume of the vapor distributor is typically hotter than the inner volume of the evaporation crucible, in order to prevent a condensation of the evaporation material on inner walls of the vapor distributor. On the other hand, a major part of the inner volume of the evaporation crucible is to be maintained around the evaporation temperature of the source material 12 (i.e., slightly below or slightly above the evaporation temperature), in order to allow the source material 12 to evaporate a bit at a time at a predetermined evaporation rate.

According to embodiments described herein that have the baffle arrangement in the vapor conduit, the first temperature can be controlled by the first heater 35 more independently of the second temperature that is provided by the second heater 25. In some embodiments, a heater controller 36 is provided for controlling the evaporation rate of the evaporation crucible by adjusting the first temperature in the evaporation crucible. The first and second heaters may be at least one of resistive and inductive heaters that may be provided in thermal contact with the walls of the evaporation crucible and/or of the vapor distributor, or that may protrude into inner volumes of the evaporation crucible and/or of the vapor distributor.

In some embodiments, which can be combined with other embodiments described herein, the evaporation crucible 30 is arranged at least partially below the vapor distributor 20, and/or the vapor distributor 20 may be arranged at least partially below the substrate support 13. The conduit length direction A and the nozzle axis may extend essentially in a vertical direction or in a direction having an angle of 45° or less relative to the vertical direction. Accordingly, the source material 12—when in a liquified state—cannot leak out of the evaporation crucible, while the material vapor can stream upwardly through the vapor conduit 40 into the vapor distributor 20 from where the vapor 15 can be directed further upwardly along the nozzle axes toward the substrate support. A compact evaporation source configured for directing vapor upwardly toward a substrate arranged “overhead” at the substrate support can be provided.

FIG. 3 is a schematic front view of an evaporation source 105 according to embodiments described herein. The evaporation source 105 of FIG. 3 may include some features or all the features of the previously described evaporation source 100 of FIGS. 1 and 2, such that reference can be made to the above explanations, which are not repeated here. Specifically, the evaporation source 105 includes the vapor distributor 20 with the plurality of nozzles 21 for directing the evaporated material toward a substrate (not shown in FIG. 3; in FIG. 3, the nozzle axes A are perpendicular to the paper plane and the vapor is directed toward the viewer).

In some embodiments, which can be combined with other embodiments described herein, the plurality of nozzles 21 are arranged in a plurality of nozzle rows 321 extending in a row direction L and arranged next to each other. For example, the vapor distributor 20 may have five, six or more nozzle rows 321, each nozzle row extending in the row direction L and having five or more nozzles, particularly ten or more, or fifteen or more nozzles. Accordingly, the vapor distributor 20 may be an “area showerhead” having the plurality of nozzles 21 arranged in a two-dimensional nozzle array providing the plurality of nozzle rows 321.

An area showerhead with a two-dimensional array of many nozzles may be beneficial as compared to a linear showerhead, because the material evaporated in the evaporation crucible can be distributed over a larger coating area on the substrate. This reduces the heat load per substrate area caused by the coating material while maintaining a high overall deposition rate that is provided by the evaporation source. Accordingly, substrate damage, such as folds or wrinkles of a delicate web substrate caused by excessive heat, can be reduced.

In some embodiments, which can be combined with other embodiments described herein, the row direction L is essentially perpendicular to the conduit length direction A of the vapor conduit. The conduit length direction A is essentially perpendicular to the paper plane of FIG. 3 and essentially corresponds to the direction of the nozzle axes of the plurality of nozzles. FIG. 1 shows a sectional plane that intersects one of the nozzle rows extending in the row direction L, wherein the row direction L is essentially perpendicular to the conduit length direction A.

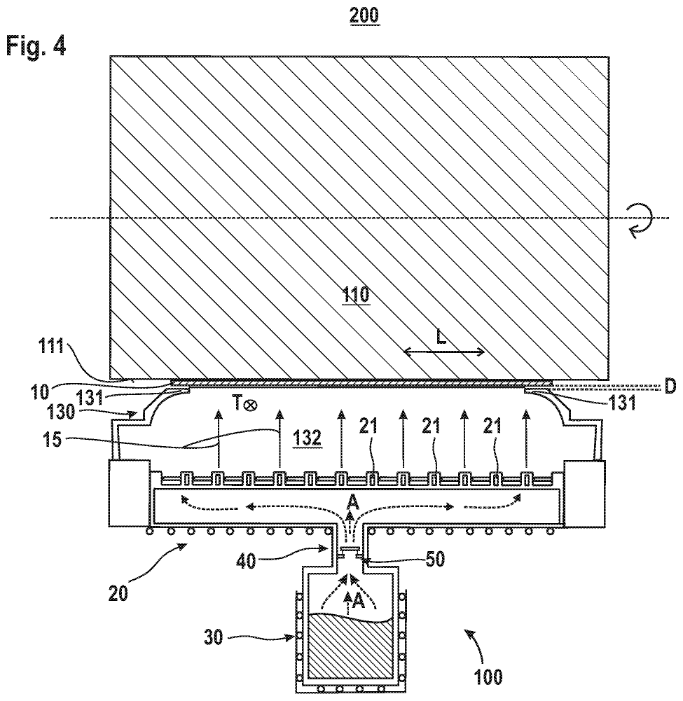

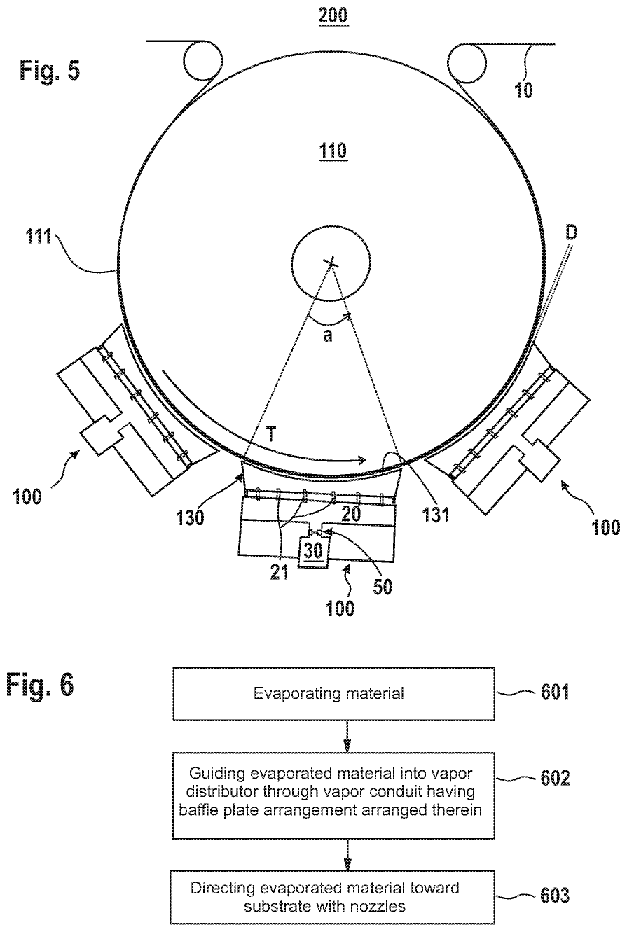

Now briefly referring to FIG. 5, in some implementations, the plurality of nozzles 21 may be directed toward a rotatable drum 110 with a curved drum surface 111 extending in a circumferential direction T, and the plurality of nozzle rows may be arranged next to each other in the circumferential direction T of the rotatable drum. By arranging the plurality of nozzles in the plurality of nozzle rows next to each other in the circumferential direction T of the rotatable drum 110, the effective area of the rotatable drum can be better utilized, and the heat load per area by the evaporated material on the substrate can be significantly reduced. Further, the row direction L may essentially correspond to the axial direction of the rotatable drum 110, and/or the conduit length direction A may essentially correspond to the radial direction of the rotatable drum 110 (see FIG. 4).

Returning to FIG. 3, the plurality of nozzle rows 321 may be shifted with respect to each other by an offset 330 in the row direction L. The offset 330 provides a misalignment between nozzles of adjacent nozzle rows along the row direction L. Hence, the substrate passing over the evaporation source 105 in a direction perpendicular to the row direction L is coated with material at different positions along the row direction L. Accordingly, the material deposition is more uniformly provided on the substrate. Correspondingly, the heat load on the substrate is provided even more uniformly, and the uniformity of the deposited coating can be improved by said offset 330.

In the example shown in FIG. 3, six nozzle rows 321 are provided. The rows are displaced by ⅙ of the nozzle-to-nozzle distance. According to some embodiments, which can be combined with other embodiments described herein, the offset 330 between two adjacent nozzle rows along the row direction L can be dY/N, wherein N is the number of nozzle rows and dY is the distance between adjacent nozzles in the row direction L. This distribution of nozzles provides a homogeneous distribution of the coating rate on the substrate and reduces hotspots by condensation energy. The offset 330 indicated by the reference numeral in FIG. 3 is provided between two neighboring rows 321. However, the offset can be provided between any of the rows. Particularly, each of the rows may be offset by the offset with respect to at least one other row.

FIG. 4 shows a schematic sectional view of a vapor deposition apparatus 200 according to embodiments of the present disclosure. FIG. 5 shows a schematic view of the vapor deposition apparatus 200 of FIG. 4 viewed along a rotation axis of a rotatable drum 110. The vapor deposition apparatus 200 may include an evaporation source 100 or several evaporation sources according to any of the embodiments described herein, such that reference can be made to the above explanations, which are not repeated here.

The vapor deposition apparatus 200 includes a substrate support being a rotatable drum 110 with a curved drum surface 111 for supporting the substrate during the deposition. The plurality of nozzles 21 of the evaporation source 100 are directed toward the curved drum surface 111, and the vapor deposition apparatus 200 is configured to move the substrate 10 on the curved drum surface 111 past the evaporation source 100. In some embodiments, several evaporation sources as described herein may be arranged one after the other in the circumferential direction T around the rotatable coating drum, such that the substrate can be subsequently coated by several evaporation sources. Different coating materials can be deposited on the substrate, or one thicker coating layer of the same coating material can be deposited on the substrate by the evaporation sources.

As it is schematically depicted in FIG. 4 and FIG. 5, the evaporation source 100 includes an evaporation crucible 30 for evaporating a material, a vapor distributor 20 with the plurality of nozzles 21 for directing the evaporated material toward the substrate 10 supported on the rotatable drum 110, and a vapor conduit 40 extending in a conduit length direction A from the evaporation crucible 30 to the vapor distributor 20, providing a fluid connection between the evaporation crucible and the vapor distributor. At least one nozzle or all nozzles of the plurality of nozzles 21 may have a nozzle axis that extends in, or is essentially parallel to, the conduit length direction A. As is depicted in FIG. 4, the conduit length direction A may essentially correspond to a radial direction of the rotatable drum 110.

In some embodiments, which can be combined with other embodiments described herein, a baffle arrangement 50 may be arranged in the vapor conduit 40. The baffle arrangement 50 reduces heat radiation from the vapor distributor into the evaporation crucible through the vapor conduit and/or prevents material splashes from the evaporation crucible through the plurality of nozzles toward the rotatable drum 110. Reference is made to the above explanations, which are not repeated here.

In some embodiments, which can be combined with other embodiments described herein, the plurality of nozzles 21 may be arranged in a plurality of nozzle rows extending in a row direction L and arranged next to each other in the circumferential direction T, wherein the row direction L may essentially correspond to an axial direction of the rotatable drum 110. Accordingly, the vapor distributor provides an area showerhead having a plurality of nozzles arranged in a two-dimension array for reducing the heat load per area on the substrate 10 supported on the curved drum surface 111.

As is depicted in FIG. 5, three, four or more evaporation sources 100 as described herein may be arranged one after the other in the circumferential direction T around the rotatable drum 110. Each evaporation source may define a coating window on the curved drum surface that extends over an angular range (a) of 10° or more and 45° or less. The conduit length direction A of adjacent evaporation sources may enclose an angle of 10° or more and 45° or less, respectively. Accordingly, the curved drum surface 111 of the rotatable drum 110 is utilized well for the vapor deposition on a flexible substrate, such as a metal foil, and substrate damage can be reduced because the heat load per substrate area can be kept comparatively low while maintaining a high deposition rate.

In some embodiments, which can be combined with other embodiments described herein, the vapor deposition apparatus 200 further includes an edge exclusion shield 130 extending from the evaporation source 100 toward the curved drum surface 111. The edge exclusion shield may include an edge exclusion portion 131 for masking areas of the substrate not to be coated, e.g. for masking lateral edge areas of the substrate that are to be kept free of coating material. For example, the edge exclusion portion 131 may be configured to mask two opposing lateral edges of the substrate.

The edge exclusion portion 131 may extend along the curved drum surface 111 of the rotatable drum 110 in the circumferential direction T, following a curvature of the curved drum surface, as it is schematically depicted in FIG. 6. Accordingly, the width D of a gap between the curved drum surface 111 and the edge exclusion portion 131 can be kept small (e.g., 2 mm or less) and essentially constant along the circumferential direction T, such that the edge exclusion accuracy can be improved and sharp and well-defined coating layer edges can be deposited on the substrate.

The “circumferential direction T” as used herein may be understood as the direction along the circumference of the rotatable drum 110 that corresponds to the movement direction of the curved drum surface 111 when the rotatable drum rotates around an axis. The circumferential direction T corresponds to the substrate transport direction when the substrate is moved past the evaporation source on the curved drum surface. In some embodiments, the rotatable drum 110 may have a diameter in a range of 300 to 1400 mm or larger. Reliably shielding the vapor 15 downstream of the plurality of nozzles 21 for confining the vapor 15 in a vapor propagation volume 132 and providing accurately defined and sharp coating edges is particularly difficult when a flexible substrate is coated that is moved on a curved drum surface, because the vapor propagation volume 132 and the coating window may have a complex shape in this case. Embodiments described herein enable a reliable and accurate edge exclusion and material shielding also in vapor deposition apparatuses configured to coat a web substrate provided on a curved drum surface. Specifically, the edge exclusion shield 130 may at least partially surround the vapor propagation volume 132 downstream of the plurality of nozzles 21, may confine the vapor 15 in the vapor propagation volume 132, and may provide an accurate edge exclusion through the edge exclusion portions 131.

In some embodiments, a heating arrangement for actively or passively heating the edge exclusion shield 130 may be provided. For example, the edge exclusion shield 130 may be heated to a temperature above the condensation temperature of the evaporation material, such that material condensation on the edge exclusion shield 130 can be reduced or prevented. Cleaning efforts can be reduced and the quality of the coating layer edges can be improved. For example, during vapor deposition, the edge exclusion shield 130 may be heated to a temperature of 500° C. or more.

The edge exclusion shield 130 does not contact the rotatable drum 110, such that the substrate supported on the rotatable drum 110 can move past the evaporation source 100 and past the edge exclusion shield 130 during vapor deposition. The edge exclusion shield 130 may leave a small gap between the edge exclusion shield 130 and the curved drum surface 111, e.g. a gap having a width D of 5 mm or less, 3 mm or less, 2 mm or less, or even about 1 mm or less, such that hardly any vapor 15 can propagate past the edge exclusion shield 130 in the row direction L.

The vapor deposition apparatus 200 may be a roll-to-roll deposition system for coating a flexible substrate, e.g. a foil. The substrate to be coated may have a thickness of 50 μm or less, particularly 20 μm or less, or even 6 μm or less. For example, a metal foil or a flexible metal-coated foil may be coated in the vapor deposition apparatus. In some implementations, the substrate 10 is a thin copper foil or a thin aluminum foil having a thickness below 30 μm, e.g. 6 μm or less. The substrate could also be a thin metal foil (e.g. a copper foil) coated with graphite, silicon and/or silicon oxide, or a mixture thereof, e.g. in a thickness of 150 μm or less, particularly 100 μm or less, or even down to 50 μm or less. According to some implementations, the web may further comprise graphite and silicon and/or silicon oxide. For example, the lithium may pre-lithiate the layer including graphite and silicon and/or silicon oxide.

In a roll-to-roll deposition system, the substrate 10 may be unwound from a storage spool, at least one or more material layers may be deposited on the substrate while the substrate is guided on the curved drum surface 111 of the rotatable drum 110, and the coated substrate may be wound on a wind-up spool after the deposition and/or may be coated in further deposition apparatuses.

FIG. 6 is a flow diagram illustrating a method for coating a substrate according to embodiments described herein.

In box 601, a material is evaporated in an evaporation crucible. For example, a metal such as lithium is evaporated in the evaporation crucible. The evaporation crucible may be heated to a first temperature of 500° C. or more, particularly 600° C. or more, more particularly 700° C. or more.

In box 602, the evaporated material is guided through a vapor conduit into a vapor distributor that has a plurality of nozzles, wherein the vapor conduit extends in a conduit length direction A, particularly essentially linearly from the evaporation crucible to the vapor distributor. In some embodiments, the vapor distributor is heated to a second temperature above the first temperature of the evaporation crucible, e.g. 100° C. or more above the first temperature. For example, the second temperature may be 800° C. or more, or even 900° C. or more.

In box 603, the evaporated material is directed with the plurality of nozzles from the vapor distributor toward a substrate, the plurality of nozzles having nozzle axes extending in, or essentially parallel to, the conduit length direction A. The nozzle axes and the conduit length direction A may enclose an angle of 20° or less. A coating is deposited on the substrate.

During the vapor deposition, heat radiation from the vapor distributor into the evaporation crucible and splashes from the evaporation crucible into the vapor distributor can be reduced with a baffle arrangement as described herein that is arranged in the vapor conduit.

In some embodiments, the substrate is a flexible substrate that is supported on the curved drum surface of a rotatable drum during the deposition. Specifically, the substrate may be moved past the plurality of nozzles on the curved drum surface of the rotatable drum.

During the vapor deposition in box 603, areas of the substrate not to be coated may be masked with an edge exclusion shield having an edge exclusion portion that follows a curvature of the curved drum surface in the circumferential direction. The edge exclusion portion may be arranged at a small distance from the curved drum surface along the circumferential direction, and a gap with a constant small gap width of 2 mm or less may be provided between the edge exclusion portion and the curved drum surface in the circumferential direction. The edge exclusion shield may be heated during the vapor deposition, e.g. to a temperature of 500° C. or more.

The heatable shield may define a coating window on the curved drum surface, i.e. a window where the evaporated material emitted by the plurality of nozzles of the evaporation source may impinge on the substrate while the substrate moves past the evaporation source. For example, the coating window may extend over an angle (a) of 10° or more and 45° or less in the circumferential direction. In some embodiments, three, four or more evaporation sources may be arranged around the rotatable coating drum in the circumferential direction, each evaporation source defining a coating window extending over an angle of 10° or more and 45° or less. The three or more evaporation sources may be metal sources, particularly lithium sources. Accordingly, a thick lithium layer can be deposited on the substrate.

The substrate may be a flexible foil, particularly a flexible metal foil, more particularly a copper foil or a copper-carrying foil, e.g. a foil that is coated with copper on one or both sides thereof. The substrate may have a thickness of 50 μm or less, particularly 20 μm or less, e.g. about 8 μm. Specifically, the substrate may be a thin copper foil having a thickness in a sub 20-μm range.

According to some embodiments, which can be combined with other embodiments described herein, an anode of a battery is manufactured, and the flexible substrate includes copper or consists of copper. According to some implementations, the web may further comprise graphite and silicon and/or silicon oxide. For example, the lithium may pre-lithiate the layer including graphite and silicon and/or silicon oxide.

The deposition of a metal, e.g. lithium, on a flexible substrate, e.g. on a copper substrate, by evaporation may be used for the manufacture of batteries, such as Li-batteries. For example, a lithium layer may be deposited on a thin flexible substrate for producing the anode of a battery. After assembly of the anode layer stack and the cathode layer stack, optionally with an electrolyte and/or separator therebetween, the manufactured layer arrangement may be rolled or otherwise stacked to produce the Li-battery.

While the foregoing is directed to embodiments, other and further embodiments may be devised without departing from the basic scope, and the scope is determined by the claims that follow.

1. An evaporation source, comprising:
an evaporation crucible for evaporating a material;
a vapor distributor with a plurality of nozzles for directing the evaporated material toward a substrate;
a vapor conduit extending in a conduit length direction from the evaporation crucible to the vapor distributor and providing a fluid connection between the evaporation crucible and the vapor distributor, wherein at least one nozzle of the plurality of nozzles has a nozzle axis extending in, or essentially parallel to, the conduit length direction; and
a baffle arrangement in the vapor conduit.

2. The evaporation source of claim 1, wherein the baffle arrangement blocks all linear propagation paths through the vapor conduit from the evaporation crucible to the vapor distributor.

3. The evaporation source of claim 1, wherein the baffle arrangement is configured to at least one of:
reduce heat radiation from the vapor distributor into the evaporation crucible through the vapor conduit; and
prevent material splashes from the evaporation crucible into the vapor distributor.

4. The evaporation source of claim 1, wherein the baffle arrangement comprises one or more shielding plates extending essentially perpendicular to the conduit length direction in the vapor conduit, the one or more shielding plates being fixedly mounted in the vapor conduit.

5. The evaporation source of claim 1, wherein the baffle arrangement comprises a first shielding plate that leaves a first vapor passage past the first shielding plate and a second shielding plate that leaves a second vapor passage past the second shielding plate, such that the second vapor passage does not overlap with the first vapor passage in the conduit length direction.

6. The evaporation source of claim 5, wherein the second shielding plate is arranged at a distance of 3 cm or less from the first shielding plate in the conduit length direction.

7. The evaporation source of claim 1, wherein the baffle arrangement comprises a first shielding plate and a second shielding plate, the first shielding plate is an annular plate that circumferentially abuts at an inner wall of the vapor conduit and has a round or circular opening, and the second shielding plate is a round or circular plate that is centrally arranged in the vapor conduit downstream or upstream of the opening and shields the opening.

8. The evaporation source of claim 1, wherein the plurality of nozzles is arranged in a plurality of nozzle rows extending in a row direction and arranged next to each other.

9. The evaporation source of claim 8, wherein
the plurality of nozzles is directed toward a rotatable drum,
the row direction is essentially perpendicular to the conduit length direction, and
the plurality of nozzle rows is arranged next to each other in a circumferential direction of the rotatable drum.

10. The evaporation source of claim 8, wherein the plurality of nozzle rows is shifted with respect to each other by a row offset in the row direction.

11. The evaporation source of claim 1, wherein the evaporation crucible is arranged at least partially below the vapor distributor, wherein the conduit length direction and the nozzle axis extend in a vertical direction or in a direction having an angle of 45° or less relative to the vertical direction.

12. The evaporation source of claim 1, further comprising a first heater for heating the evaporation crucible to a first temperature, a second heater for heating the vapor distributor to a second temperature above the first temperature, and a heater controller for controlling an evaporation rate by adjusting the first temperature.

13. A vapor deposition apparatus, comprising:
the evaporation source of claim 1; and
a rotatable drum with a curved drum surface for supporting the substrate,
wherein the plurality of nozzles of the evaporation source is directed toward the curved drum surface, and the vapor deposition apparatus is configured to move the substrate on the curved drum surface past the evaporation source.

14. The vapor deposition apparatus of claim 13, further comprising an edge exclusion shield extending from the evaporation source toward the curved drum surface and comprising an edge exclusion portion for masking areas of the substrate not to be coated.

15. The vapor deposition apparatus of claim 14, wherein the edge exclusion portion extends along the curved drum surface in a circumferential direction of the curved drum surface and follows a curvature thereof.

16. A method for coating a substrate in a vacuum chamber, comprising:
evaporating a material in an evaporation crucible;
guiding the evaporated material through a vapor conduit into a vapor distributor with a plurality of nozzles, the vapor conduit extending in a conduit length direction;
directing the evaporated material with the plurality of nozzles toward the substrate, the plurality of nozzles having nozzle axes extending in, or essentially parallel to, the conduit length direction; and
reducing heat radiation from the vapor distributor into the evaporation crucible and preventing splashes from the evaporation crucible into the vapor distributor with a baffle arrangement arranged in the vapor conduit.

17. The method of claim 16, further comprising:
moving the substrate past the plurality of nozzles on a curved drum surface of a rotatable drum; and
masking areas of the substrate not to be coated with an edge exclusion shield that follows a curvature of the curved drum surface.

18. The method of claim 16, wherein the plurality of nozzles is arranged in a plurality of nozzle rows extending in a row direction and arranged next to each other, each nozzle row having five or more nozzles with nozzle axes extending in, or essentially parallel to, the conduit length direction.

19. A vapor deposition apparatus, comprising:
a rotatable drum with a curved drum surface for supporting a substrate; and
at least one evaporation source, comprising:
an evaporation crucible for evaporating a material;
a vapor distributor with a plurality of nozzles directed toward the curved drum surface, the plurality of nozzles arranged in a plurality of nozzle rows extending in a row direction and arranged next to each other; and
a vapor conduit extending linearly in a conduit length direction from the evaporation crucible to the vapor distributor and providing a fluid connection between the evaporation crucible and the vapor distributor, wherein the nozzles have nozzle axes extending in or essentially parallel to the conduit length direction.

20. The vapor deposition apparatus of claim 19, comprising at least three evaporation sources arranged one after the other in a circumferential direction around the rotatable drum, each evaporation source defining a coating window on the curved drum surface extending over an angular range of 10° or more and 45° or less, wherein conduit length directions of adjacent evaporation sources enclose an angle of 10° or more and 45° or less, respectively.
